(19) United States
(12) Patent Application Publication
(10) Pub. No.: US 2024/0247372 A1
(43) Pub. Date: Jul. 25, 2024

(54) SUBLIMATION GAS SUPPLY SYSTEM AND SUBLIMATION GAS SUPPLY METHOD WITH BUFFER TANK

(71) Applicant: L'Air Liquide, Societe Anonyme pour l'Etude et l’Exploitation des Procedes Georges Claude, Paris (FR)

(72) Inventors: Xingyong ZHANG, TOKYO (JP); Terumasa KOURA, Tokyo (JP); Sayaka SUZUKI, Tokyo (JP); Chikako UNO, Toyko (JP)

(73) Assignee: L'Air Liquide, Societe Anonyme pour l'Etude et l’Exploitation des Procedes Georges Claude, Paris (FR)

(21) Appl. No.: 18/577,936

(22) PCT Filed: Jul. 5, 2022
(86) PCT No.: PCT/EP2022/068563

§ 371 Date: Jan. 9, 2024

(30) Foreign Application Priority Data
Jul. 9, 2021 (JP) JP 2021-114451

(51) Int. Cl. C23C 16/448; C23C 16/455

(52) U.S. Cl. CPC C23C 16/4481; C23C 16/45561

(57) ABSTRACT

The provision of a sublimation gas supply system and sublimation gas supply method, where there is no decrease in the utilisation rate of the sublimation gas even when the solid material vessel is replaced. Sublimation gas supply system, having: 1st vessel; 1st heater that heats 1st vessel; 1st buffer tank that stores sublimation gas; dilution gas channel for introducing dilution gas into 2nd channel, that is connected to 1st connector C1 in 2nd channel; 1st flow control device for controlling flow, provided between 1st connector C1 and 1st buffer tank on the 2nd channel; 2nd flow control device for controlling flow, provided on the dilution gas channel; and mixing vessel, provided on the 2nd channel, for mixing the 1st sublimation gas and dilution gas brought together by means of 1st connector C1.

### CROSS-REFERENCE TO RELATED APPLICATIONS

This application is a § 371 of International PCT Application PCT/EP2022/068563, filed Jul. 5, 2022, which claims § 119(a) foreign priority to Japanese patent application JP 2021-114451, filed Jul. 9, 2021.

### TECHNICAL FIELD

The present disclosure relates to a sublimation gas supply system and sublimation gas supply method for supplying solid material sublimation gas to a subsequent process.

### BACKGROUND TECHNOLOGY

In order to manufacture microelectronic devices such as semiconductor integrated devices and liquid crystal panels, it is necessary to form films of various materials on the substrate. In recent years, various members have been dry-coated to improve member characteristics such as strength. PVD (physical vapour deposition), CVD (chemical vapour deposition) and ALD (atomic layer deposition), etc., are widely known as these film-forming methods and coating methods.

Advances in the semiconductor industry have brought strict requirements for films, resulting in lower precursor vapour pressures being used in film formation. Examples of precursors for film formation are inorganic compounds, organometallic compounds, etc. of aluminium, barium, bismuth, chromium, cobalt, copper, gold, hafnium, indium, iridium, iron, lanthanum, lead, magnesium, molybdenum, nickel, niobium, platinum, ruthenium, silver, strontium, tantalum, titanium, tungsten, yttrium and zirconium. Also, in carbon-free film formation, inorganic metal compounds are commonly used as precursor for dry-coating. These materials have low vapour pressure and so when solid material is introduced into the film formation chamber, they must be supplied sublimated. In conventional methods, starting material powder is contained in a vapour production chamber, the starting material powder is heated to produce saturated vapour, and carrier gas is brought into contact with the starting material vapour to obtain carrier gas containing starting material powder, which is then supplied to a film-forming device (see Patent document 1, for example).

### PRIOR ART DOCUMENTS

### Patent Documents

[Patent document 1] Japanese unexamined patent H3-141192

### Outline of the Invention

### Problem to be Solved by the Invention

However, with the abovementioned conventional device it is necessary to discharge the sublimation gas in the storage chamber when the vapour generation chamber is replaced. Therefore in conventional devices the utilisation rate of the sublimation gas is lowered.

The aim of the present disclosure is the provision of a sublimation gas supply system and supply method therefor, where there is no decrease in the utilisation rate of the sublimation gas even when the solid material vessel is replaced.

In what follows, for ease of reference, specific features of the disclosed invention, such as, for example, vessels, flow control devices or solid materials, may be referred to as “1st”, “2nd”, “3rd”, etc., whereby the “1st” is distinct from the “2nd”, the “1st” and “2nd” are distinct from the “3rd” etc. It should be noted that, when reference is made to an n-th feature x (with n>1), this does not necessarily mean that the corresponding embodiment of the invention necessarily presents all of the features x from 1st feature x up to the (n−1)-th feature x. For example, an embodiment with the 3rd buffer tank as defined below may, but does not necessarily, include a 2nd buffer tank as also defined below.

### Means of Solving the Problem

Presently disclosed is:
a sublimation gas supply system for supplying solid material sublimation gas to a subsequent process, where the sublimation gas supply system has
a vessel, hereafter “1st vessel”, that houses a 1st solid material,
a 1st heater that heats said 1st vessel so that said 1st solid material sublimates to produce a 1st sublimation gas,
a 1st buffer tank that stores sublimation gas,
a 1st channel that introduces said 1st sublimation gas into said 1st buffer tank,
a 2nd channel for supplying said 1st sublimation gas, delivered from said 1st buffer tank, to a subsequent process,
a dilution gas channel connected to a 1st connector in said 2nd channel, for introducing dilution gas into said 2nd channel,
a 1st flow control device for controlling flow, provided between said 1st connector and said 1st buffer tank on said 2nd channel,
a 2nd flow control device for controlling flow, provided on said dilution gas channel, and
a mixing vessel, provided on said 2nd channel, for mixing said dilution gas and said 1st sublimation gas brought together by means of said 1st connector.

With this configuration, when the 1st vessel is to be replaced with another vessel containing the 1st solid material, it is not necessary to discharge the 1st sublimation gas from the 1st buffer tank. Therefore, the 1st sublimation gas can be supplied to a subsequent process with no decrease in the utilisation rate of the sublimation gas.

The abovementioned configuration may also have: a 2nd buffer tank that stores said dilution gas, provided on said dilution gas channel,
a 1st valve, provided on said 1st channel,
a 2nd valve, provided between said 1st connector and said 1st buffer tank on said 2nd channel, and
a 3rd valve, provided between said 1st connector and said 2nd buffer tank on said dilution gas channel.

With this configuration it is possible to appropriately control the flow of the 1st sublimation gas and dilution gas.

The abovementioned configuration may also have a 1st discharge channel for discharging said 1st sublimation gas from said 1st buffer tank, provided between said 1st valve and said 1st buffer tank on said 1st channel,
a 3rd flow control device for controlling flow, provided between said mixing vessel and said subsequent process on said 2nd channel, and
a discharge gas channel that discharges gas on said 2nd channel, provided between said mixing vessel and said 3rd flow control device on said 2nd channel.

With this configuration it is possible to appropriately discharge sublimation gas when, in controlling the sublimation gas system, it is necessary to remove sublimation gas in the system (for example, 1st sublimation gas).

The abovementioned disclosure may also have a 1st buffer tank heater for heating said 1st buffer tank, and
a mixing vessel heater for heating said mixing vessel.

With this configuration it is possible to prevent the sublimation gas from solidifying when the dilution gas and sublimation gas are mixed.

The abovementioned disclosure may also have a 2nd vessel that houses a 2nd solid material,
a 2nd heater that heats said 2nd vessel so that said 2nd solid material sublimates to produce a 2nd sublimation gas, and
a 3rd channel that introduces said 2nd sublimation gas into said 1st buffer tank. Here, said 1st solid material and said 2nd solid material are the same solid material.

The “same material” means that they comprise essentially the same material.

With this configuration, when the 1st sublimation gas pressure in the 1st vessel has decreased (i.e. the amount of 1st solid material has decreased to less than the predetermined amount) it is possible to introduce the 2nd sublimation gas from the 2nd vessel into the 1st buffer tank without removing the 1st sublimation gas from the 1st buffer tank. This is because here the 1st sublimation gas and 2nd sublimation gas comprise the same sublimation gas. “Said 1st solid material and said 2nd solid material are the same solid material” means that they comprise essentially the same material.

The abovementioned disclosure may also have a 2nd vessel that houses a 2nd solid material,
a 2nd heater that heats said 2nd vessel so that said 2nd solid material sublimates to produce a 2nd sublimation gas,
a 3rd buffer tank for storing said 2nd sublimation gas,
a 4th channel for introducing said 2nd sublimation gas into said 3rd buffer tank,
a 5th channel for supplying said 2nd sublimation gas, delivered from said 3rd buffer tank, into said 2nd channel between said mixing vessel and said 1st buffer tank,
a 4th flow control device for controlling flow, provided on said 5th channel, and
a valve provided on said 5th channel. Here, said 1st solid material and said 2nd solid material are different solid materials. “Said 1st solid material and said 2nd solid material are different solid materials” means that they comprise essentially different materials.

With this configuration it is possible to stop the supply of 1st sublimation gas from the 1st vessel, then supply the 2nd sublimation gas from the 2nd vessel to a subsequent process.

The abovementioned disclosure can also be equipped with a 2nd pressure gauge that measures the pressure inside said 1st buffer tank, and a controller, where
at start-up, when said 2nd pressure gauge has reached a predetermined pressure, said controller exerts control to open said 2nd valve so that said 1st sublimation gas flows through said 1st channel.

With this configuration it is possible to appropriately provide the 1st sublimation gas to a subsequent process. Here, for example, if the 1st solid material is AlCl₃, the predetermined pressure is 1×10⁻⁶ to 1×10⁻¹ atm. Or, if the 1st solid material is MoO₂Cl₂, the predetermined pressure is ≥1 kPa, ≤50 kPa. The predetermined pressure value can be converted to the predetermined concentration of the 1st sublimation gas.

The abovementioned disclosure can also be equipped with a controller, and
may be configured so that in stop control, said controller exerts control to close said 2nd valve and said 3rd valve. By closing the 2nd and 3rd valve, the supply of 1st sublimation gas from said 1st buffer tank, respectively of dilution gas from the 2nd buffer tank, to the subsequent process is interrupted.

With this configuration it is possible to prevent the flow of dilution gas into the 1st buffer tank. Therefore it is possible to restart the sublimation gas supply system without discharging the sublimation gas stored in the 1st buffer tank. Any of (1) to (3) below may be adopted as a specific control method.
a. Closure of the 2nd and 3rd valves simultaneously.
b. Closure of the 2nd valve followed by closure of the 3rd valve.
c. Closure of the 3rd valve followed by closure of the 2nd valve.

When that described above is also equipped with a controller,
during steady-state operation, or depending on the conditions of said subsequent process, said controller selects at least one from the group consisting of said 1st flow control device and said 2nd flow control device to regulate the concentration of said 1st sublimation gas to be introduced into said subsequent process.

With this configuration, if the subsequent process changes the concentration of the 1st sublimation gas, it is possible to change the 1st sublimation gas concentration appropriately in steady-state operation.

Another disclosure is a sublimation gas supply method for supplying solid material sublimation gas to a subsequent process, having
a 1st heating step whereby a 1st vessel that houses a 1st solid material is heated to produce a 1st sublimation gas from the 1st solid material,
a 1st introduction step whereby said 1st sublimation gas is introduced into a 1st buffer tank,
a 1st supply step whereby said 1st sublimation gas delivered from said 1st buffer tank is supplied to a subsequent process,
a 1st dilution step whereby dilution gas is supplied to said 1st sublimation gas delivered from said 1st buffer tank,
a 1st flow control step whereby the flow of said 1st sublimation gas delivered from said 1st buffer tank is controlled, and
a 2nd flow control step whereby the flow of said dilution gas supplied from said dilution gas channel is controlled.

Another disclosure to that described above has a 2nd heating step whereby a 2nd vessel that houses a 2nd solid material is heated to produce a 2nd sublimation gas from the 2nd solid material,
a 2nd introduction step whereby said 2nd sublimation gas is introduced into the 1st buffer tank, and
a 1st switching step whereby said 1st introduction step is stopped and switched to said 2nd introduction step. Here, said 1st solid material and said 2nd solid material are the same solid material.

With the abovementioned disclosure, when the 1st sublimation gas pressure in the 1st vessel has decreased (i.e. the amount of 1st solid material has decreased to less than the predetermined amount) it is possible to introduce the 2nd sublimation gas from the 2nd vessel into the 1st buffer tank without removing the 1st sublimation gas from the 1st buffer tank.

The abovementioned invention may also have a 2nd heating step whereby a 2nd vessel that houses a 2nd solid material is heated to produce a 2nd sublimation gas from the 2nd solid material,
a 2nd introduction step whereby said 2nd sublimation gas is introduced into a 3rd buffer tank,
a 2nd supply step whereby said 2nd sublimation gas delivered from said 3rd buffer tank is supplied to a subsequent process,
a 2nd dilution step whereby said dilution gas is supplied to said 2nd sublimation gas delivered from said 3rd buffer tank, and
a 2nd switching step whereby said 1st introduction step and said 1st supply step are stopped and switched to said 2nd introduction step and said 2nd supply step. Here, said 1st solid material and said 2nd solid material are different solid materials.

### BRIEF DESCRIPTION OF THE FIGURES

FIG. 1 is a summary diagram of a sublimation gas supply system according to Embodiment 1.

FIG. 2 is a summary diagram of a sublimation gas supply system according to Embodiment 2.

FIG. 3 is a summary diagram of a sublimation gas supply system according to Embodiment 3.

### DETAILED DESCRIPTION OF THE INVENTION

### Modes of Embodiment of the Invention

Several embodiments of the present invention are described below. The embodiments described below are examples of the present invention. The present invention is in no way limited by the following embodiments, and also includes a number of variant modes which are implemented within a scope that does not alter the meaning of the present invention.

It should be noted that not all of the constituent elements described below are necessarily essential constituent elements of the present invention.

### Embodiment 1

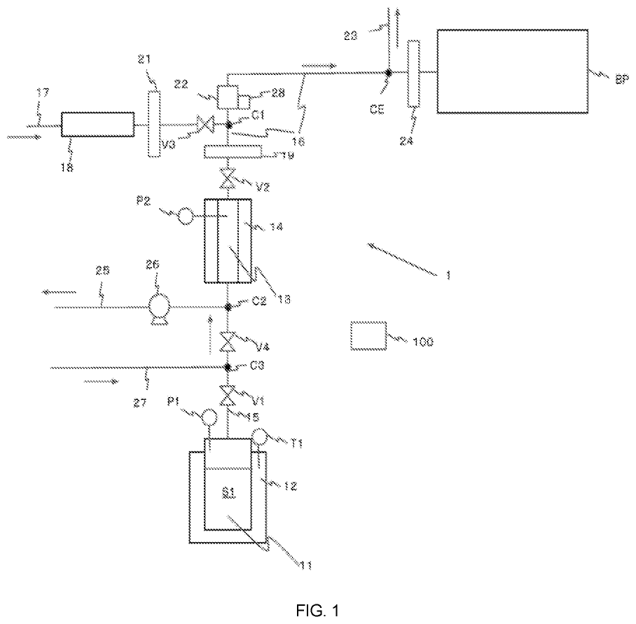

FIG. 1 is a summary diagram of a sublimation gas supply system. The arrows in FIG. 1 show the direction of flow of the various gases (for example, sublimation gas, dilution gas).

This embodiment has one vessel. It also has one buffer tank. The buffer tank stores the sublimation gas produced from the vessel.

Here, 1st vessel 11 houses 1st solid material S1. 1st vessel 11 may be a tray type or a trayless type. The tray type comprises a single tray or multiple trays installed inside the vessel, where the solid material is placed on the tray(s). The trayless type is such that the solid material is placed inside the vessel as is.

1st heater 12 can heat 1st vessel 11. Heating 1st vessel 11 results in the production of a 1st sublimation gas from 1st solid material S1. In FIG. 1, 1st heater 12 is a jacket type that covers 1st vessel 11, but is not limited to this. For example, 1st heater 12 may be an oven type that heats the entire surface of 1st vessel 11. 1st thermometer T1 measures the temperature of 1st heater 12. Then 1st heater 12 is controlled based on the measured temperature. It should be noted that 1st vessel 11 may be equipped with 1st pressure gauge P1 that measures the pressure inside 1st vessel 11.

The 1st sublimation gas produced from 1st vessel 11 passes through 1st channel 15 and is introduced into 1st buffer tank 13. In other words, 1st vessel 11 is connected to 1st buffer tank 13 via 1st channel 15. As shown in FIG. 1, 1st buffer tank heater 14 may be provided in 1st buffer tank 13. For example, 1st buffer tank heater 14 may be a jacket type that covers 1st buffer tank heater 14. 1st buffer tank 13 may be equipped with 2nd pressure gauge P2. 2nd pressure gauge P2 measures the pressure inside 1st buffer tank 13. On 1st channel 15 there is 3rd connector C3 that connects to purge gas channel 27. Purge gas flows in purge gas channel 27. The purge gas is, for example, oxygen, nitrogen or hydrogen. Or the purge gas may be an inert gas. Examples are helium, argon and neon. A valve (not shown in the figure) may be provided on purge gas channel 27. When purge gas is supplied to 1st channel 15, the valve (not shown in the figure) on purge gas channel 27 may be open. On 1st channel 15 there is also 2nd connector C2 that connects to 1st discharge channel 25 for discharging the sublimation gas stored in 1st buffer tank 13. Pump 26 is provided on 1st discharge channel 25. It should be noted that a valve (not shown in the figure) may be provided on 1st discharge channel 25.

Next, the stored sublimation gas is supplied through 2nd channel 16 to subsequent process BP. On 2nd channel 16 there is also 1st connector C1. 1st connector C1 connects to dilution gas channel 17 to introduce dilution gas.

The system may also be equipped with 2nd buffer tank 18 on dilution gas channel 17. 2nd buffer tank 18 stores dilution gas. Here, the dilution gas is, for example, an inert gas such as nitrogen gas, a rare gas such as argon gas, or hydrogen gas.

The dilution gas meets the sublimation gas discharged from 1st buffer tank 13 in 1st connector C1. Then the dilution gas and the sublimation gas are mixed in mixing vessel 22 provided on 2nd channel 16. Here, when the dilution gas and the sublimation gas are mixed, mixing vessel 22 may have any configuration. For example, mixing vessel 22 may be an extension pipe, gas mixer or venturi pipe. Mixing vessel 22 may be equipped with mixing vessel heater 28. In this case, even if the dilution gas temperature is lower than the sublimation gas temperature, it is possible to prevent solidification of the sublimation gas. Furthermore, in 2nd channel 16, discharge gas connector CE may be provided between mixing vessel 22 and subsequent process BP. Discharge gas connector CE is connected to discharge gas channel 23. A valve (not shown in the figure) may be provided between the pump (not shown in the figure) and discharge gas connector CE on discharge gas channel 23. There may also be a heater (not shown in the figure) on 2nd channel 16, to prevent solidification of the sublimation gas.

The sublimation gas supply system in this embodiment is equipped with a flow control device that controls the sublimation gas flow and dilution gas flow respectively. Specifically, in 2nd channel 16, 1st flow control device 19 is provided between 1st connector C1 and 1st buffer tank 13. In dilution gas channel 17, 2nd flow control device 21 is provided between 1st connector C1 and 2nd buffer tank 18. For example, controller 100 (described in detail below) controls 1st flow control device 19 and 2nd flow control device 21. As a result, it is possible to change the sublimation gas concentration appropriately. Therefore sublimation gas can be supplied at an appropriate concentration to subsequent process BP. Also, 2nd channel 16 may be equipped with 3rd flow control device 24 between discharge gas connector CE and subsequent process BP. A valve (not shown in the figure) may be provided between 3rd flow control device 24 and discharge gas connector CE. An example of a flow control device is a mass flow meter. Another example of a flow control device is a device comprising a flow control valve and a flow meter. Or the flow control device can be another device that can control the flow regulation valve using differential pressure by controlling the pressure before and after the channel.

The sublimation gas supply system in this embodiment is equipped with various valves. 1st valve V1 is provided on 1st channel 15. As shown in FIG. 1, 1st valve V1 may be provided between 3rd connector C3 and 1st vessel 11. 2nd valve V2 is provided on 2nd channel 16. Specifically, 2nd valve V2 is provided between 1st connector C1 and 1st buffer tank 13. 3rd valve V3 is provided on dilution gas channel 17. It is provided on dilution gas channel 17 between 1st connector C1 and 2nd flow control device 21. And 4th valve V4 may also be provided. 4th valve V4 is provided on 1st channel 15 between 2nd connector C2 and 3rd connector C3. Here, “on channel” includes piping connecting the elements, and inlets and outlets of the respective vessels and buffer tanks. Valves on the inlets and outlets of the respective vessels and buffer tanks may be used instead of “valves” on the channels.

The sublimation gas supply system in this embodiment is also equipped with controller 100. Controller 100 may be connected to the respective valves, flow control devices, pressure gauges, pumps and subsequent processes. For example, the sublimation gas supply system in this embodiment can be controlled as described below. The following operation may be performed, for example, by the arithmetic circuit of controller 100 reading a control program from the memory circuit of controller 100. Controller 100 may be equipped with an arithmetic processing unit and a memory unit that stores the control program. The arithmetic processing unit can, for example, be an MPU, CPU or the like. The memory unit can, for example, be a memory or the like. However, following operations need not necessarily be performed using controller 100. The operator may perform some of the operations.

### (1st Heating Step)

Controller 100 controls 1st heater 12 so that it heats 1st vessel 11 that houses 1st solid material S1. Then the 1st sublimation gas is produced from 1st solid material S1.

### (1st Supply Step)

There is a 1st introduction step to introduce the 1st sublimation gas into 1st buffer tank 13. Specifically, controller 100 exerts control to open 1st valve V1 and 4th valve V4. Then the 1st sublimation gas passes through 1st channel 15 and is introduced into 1st vessel 11. Next, the 1st sublimation gas discharged from 1st buffer tank 13 is supplied to subsequent process BP. At that time, controller 100 exerts control to open 2nd valve V2.

### (1st Dilution Step)

Dilution gas is supplied during this 1st supply step.

In the 1st dilution step, controller 100 controls 3rd valve V3 so that 3rd valve V3 is open.

### (1st Flow Control Step and 2nd Flow Control Step)

Controller 100 controls the 1st flow control device and 2nd flow control device respectively so that the concentration of the 1st sublimation gas is as required for subsequent process BP.

Then, for example, at start-up the sublimation gas supply system in this embodiment can exert control as follows.

### (Start-Up Mode)

1) At the command of controller 100, pump 26 is operated to create a vacuum (an essentially vacuum state) in 1st buffer tank 13.
2) 2nd pressure gauge P2 measures the pressure inside 1st buffer tank 13.
3) From the values measured by 2nd pressure gauge P2, a determination unit (not shown in the figure) of controller 100 may determine whether or not the inside of 1st buffer tank 13 is in a vacuum state.
4) When pump 26 is operating, only 1st discharge channel 25 is open.
5) If 1st discharge channel 25 is equipped with a valve, controller 100 exerts control to open that valve.
a. Controller 100 controls the various valves (V2, V3 and V4) on the other channels connected to 1st buffer tank 13 so that they are closed. At this time, 1st heater 12 may heat 1st vessel 11. In that case, the 1st sublimation gas from 1st solid material S1 is produced in 1st vessel 11.
b. When it is determined that the inside of 1st buffer tank 13 is in a vacuum state, controller 100 exerts control to open 1st valve V1 and 4th valve V4. At this time, the valves of 1st discharge channel 25 and purge channel 27, not shown in the figures, are closed. Then the 1st sublimation gas housed in 1st vessel 11 passes through 1st channel 15 and is supplied to 1st buffer tank 13.
c. If the pressure measured by 2nd pressure gauge P2 exceeds the predetermined pressure, controller 100 exerts control to open 2nd valve V2. And controller 100 exerts control to open 3rd valve V3 so that dilution gas can be supplied to 2nd channel 16.
d. Controller 100 can appropriately control 1st flow control device 19 and 2nd flow control device 21 so that the concentration of the 1st sublimation gas is as predetermined (for example, the concentration required for subsequent process BP).

Here, mixing vessel heater 28 provided for mixing vessel 22 may be controlled in accordance with the dilution gas temperature. For example, if the dilution gas temperature is lower than the 1st sublimation gas temperature, it is presumed that the 1st sublimation gas temperature will decrease. As a result, the 1st sublimation gas may solidify. It is possible to prevent solidification of the 1st sublimation gas by heating mixing vessel 22 using mixing vessel heater 28.

Also, even if 1st vessel 11 is heated continuously, 1st pressure gauge P1 may not reach the predetermined pressure. Here, for example, the pressure value measured by 1st pressure gauge P1 can be converted to the 1st sublimation gas concentration based on the pressure-concentration conversion table provided in the controller. If the predetermined pressure is not reached, it means that there is an insufficient amount of 1st solid material S1 in 1st vessel 11. At this time, for example, controller 100 exerts control to close 1st valve V1. Then 1st vessel 11 can be removed and another vessel containing the 1st solid material can be attached. In this case, 1st buffer tank 13 contains the 1st sublimation gas from the 1st solid material, and so after the other vessel is attached, it is possible to introduce the 1st sublimation gas from another vessel into 1st buffer tank 13 by opening 1st valve V1. In other words, when 1st vessel 11 is replaced with another vessel, the sublimation gas supply system can be operated without reverting 1st buffer tank 13 to a vacuum state (that is, without discharging the 1st sublimation gas remaining in 1st buffer tank 13). Therefore it is possible to improve upon the sublimation gas utilisation rate of conventional systems.

The sublimation gas supply system in this embodiment can exert the following control during steady-state operation. Here, steady-state operation means a state in which sublimation gas is continuously supplied to subsequent process BP.

Controller 100 controls at least one chosen from the group consisting of 1st flow control device 19 and 2nd flow control device 21 so that the 1st sublimation gas concentration is as required for subsequent process BP. When the subsequent process is a film-forming device, supply can proceed continuously without changing the 1st sublimation gas concentration, even if the film-forming conditions are changed during steady-state operation. In other words, even if subsequent process BP requires a different sublimation gas concentration, sublimation gas can be supplied to subsequent process BP without stopping the sublimation gas supply system.

In stop control, the sublimation gas supply system in this embodiment can exert the following control.

Controller 100 may control 2nd valve V2 and 3rd valve V3 so that 2nd valve V2 and 3rd valve V3 close simultaneously. This control can prevent the flow of dilution gas into 1st buffer tank 13. And it can prevent the introduction of dilution gas into 2nd buffer tank 18. Therefore it is possible to restart the sublimation gas supply system without discharging the sublimation gas stored in 1st buffer tank 13 or the dilution gas stored in 2nd buffer tank 18.

### Embodiment 2

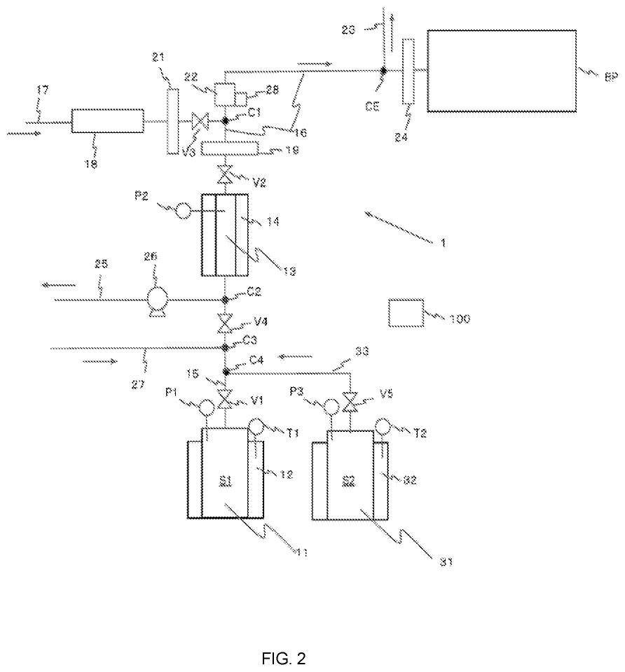

As shown in FIG. 2, the sublimation gas supply system described in Embodiment 2 comprises the sublimation gas supply system described in Embodiment 1 plus 2nd vessel 31 that houses 2nd solid material S2. It is configured such that a 2nd sublimation gas produced from 2nd vessel 31 can be supplied to 1st buffer tank 13. Here, in this embodiment, 1st solid material S1 and 2nd solid material S2 comprise the same solid material. The description focusses on differences to Embodiment 1.

2nd vessel 31 may be a tray type or a trayless type. 2nd heater 32 can heat 2nd vessel 31. On heating 1st vessel 31, a 2nd sublimation gas is produced from 2nd solid material S2. 2nd heater 32 may be jacket type or oven type. 2nd thermometer T2 measures the temperature of 2nd heater 32. And 2nd heater 32 is controlled based on the measured temperature. It should be noted that 2nd vessel 31 may be equipped with 3rd pressure gauge P3 that measures the pressure inside 2nd vessel 31.

The 2nd sublimation gas produced from 2nd vessel 31 passes through 3rd channel 33 and 1st channel 15 and is introduced into 1st buffer tank 13. Here, 3rd channel 33 is connected to 1st channel 15 and 4th connector C4. In FIG. 2, 4th connector C4 is provided between 1st valve V1 and 3rd connector C3, but there are no limitations provided that it is between 1st valve V1 and 4th valve V4. The sublimation gas supply method of this embodiment is described below.

### (2nd Heating Step)

Controller 100 exerts control to close 5th valve V5. Next, controller 100 exerts control to heat 2nd vessel 31 that houses 2nd solid material S2. This produces a 2nd sublimation gas from 2nd solid material S2.

### (2nd Introduction Step)

Controller 100 exerts control to open 5th valve V5 and 4th valve V4. Then the 2nd sublimation gas is introduced into the 1st buffer tank.

### (1st Switching Step)

The 1st introduction step described in Embodiment 1 is stopped. In other words, controller 100 exerts control to close 1st valve V1. Thereby switching from the 1st introduction step to the 2nd introduction step.

### (Vessel-Replacing Step)

After the 1st switching step, 1st vessel 11 may be replaced with another vessel containing the 1st solid material. Therefore if the amount of 1st sublimation gas produced from 1st vessel 11 has decreased, 2nd sublimation gas from the 2nd vessel can be supplied into 1st buffer tank 13. Here, the 1st sublimation gas and 2nd sublimation gas of this embodiment can be from the same solid material. Therefore when switching from the 1st introduction step to the 2nd introduction step there is no need to remove the stored sublimation gas from 1st buffer tank 13. It is therefore possible to achieve a higher sublimation gas utilisation rate than is achievable with conventional methods.

### Embodiment 3

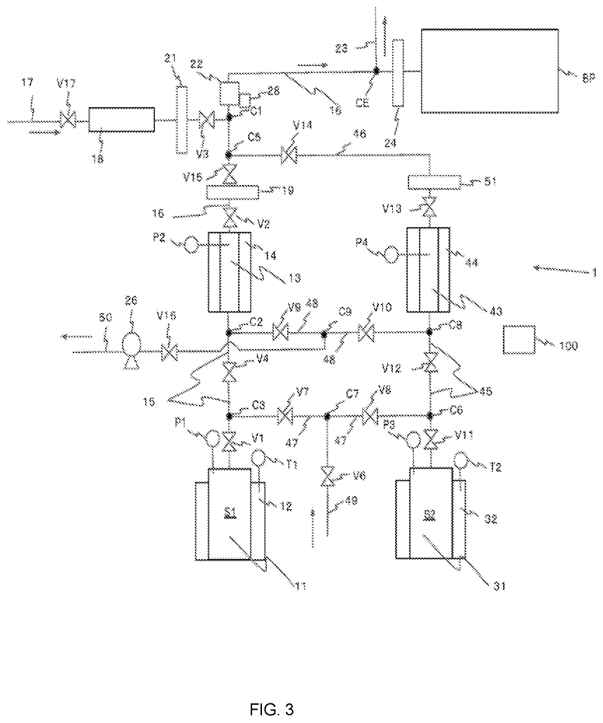

As shown in FIG. 3, the sublimation gas supply system described in Embodiment 3 comprises the sublimation gas supply system described in Embodiment 1 plus 2nd vessel 31 that houses 2nd solid material S2. And it is configured such that the 2nd sublimation gas produced from 2nd vessel 31 can be supplied into 3rd buffer tank 43. Here, in this embodiment, 1st solid material S1 and 2nd solid material S2 comprise different solid materials.

The 2nd sublimation gas produced from 2nd vessel 31 passes through 4th channel 45 and is introduced into 3rd buffer tank 43. In other words, 2nd vessel 31 and 3rd buffer tank 43 are connected via 4th channel 45. As shown in FIG. 3, 3rd buffer tank heater 44 may be provided for 3rd buffer tank 43. For example, 3rd buffer tank heater 44 may be a jacket type that covers 1st buffer tank heater 44. 3rd buffer tank 43 may be equipped with 4th pressure gauge P4. 4th pressure gauge P4 measures the pressure inside 3rd buffer tank 43.

Next, stored 2nd sublimation gas passes through 5th channel 46 and is supplied to subsequent process BP. Specifically, as shown in FIG. 3, 5th channel 46 is connected to 5th connector C5 provided between 1st connector C1 and 1st flow control device 19. It should be noted that 5th connector C5 may be provided between 1st connector C1 and mixing vessel 22.

The description of the various channels in this embodiment focusses on differences between Embodiment 1 and Embodiment 2.

The channel through which purge gas flows comprises 6th channel 47 and 8th channel 49. 6th channel 47 is connected to 3rd connector C3 on 1st channel 15 and 6th connector C6 of 4th channel 45. And 7th connector C7 is provided on 6th channel 47. This 7th connector C7 is connected to 8th channel 49. 6th valve V6, 7th valve V7 and 8th valve V8 are provided on 8th channel 49, between 3rd connector C3 and 7th connector C7, and between 6th connector C6 and 7th connector C7, respectively.

For example, when there is a wish to purge 1st buffer tank 13 and 1st channel 15, controller 100 exerts control to close 8th valve V8 and 2nd valve V2. And controller 100 exerts control to open 4th valve V4, 6th valve V6 and 7th valve V7. This allows the introduction of purge gas into 1st buffer tank 13 and 1st channel 15.

The channel through which discharge gas (for example, sublimation gas) flows is described next. The channel through which sublimation gas flows comprises 7th channel 48 and 9th channel 50. 7th channel 48 is connected to 2nd connector C2 on 1st channel 15, and 8th connector C8 of 4th channel 45. Also, 9th connector C9 is provided on 7th channel 48. This 9th connector C9 is connected to 9th channel 50. 16th valve V16, 9th valve V9 and 10th valve V10 are provided on 9th channel 50, between 2nd connector C2 and 9th connector C9, and between 8th connector C8 and 9th connector C9, respectively. For example, when there is a wish to discharge the sublimation gas stored in 1st buffer tank 13 and 1st channel 15, controller 100 exerts control to close 4th valve V4 and 10th valve V10. And controller 100 exerts control to open 9th valve V9 and 16th valve V16. Next, pump 26 is operated and it is possible to discharge the discharge gas (here, sublimation gas).

Next, 5th channel 46 will be described. 5th channel 46 connects 3rd buffer tank 43 and 5th connector C5. 3rd flow control device 51 is provided on 5th channel 46. 4th flow control device 51 is, for example, a mass flow meter. 4th flow control device 51 controls the flow of the 2nd sublimation gas.

Also, 5th channel 46 may be equipped with a valve. As shown in FIG. 3, a valve (13th valve in FIG. 3) may be provided between 3rd buffer tank 43 and 4th flow control device 51. Also, a valve (14th valve in FIG. 3) may be provided between 4th flow control device 51 and 5th connector C5.

Furthermore, 15th valve V15 is provided on 2nd channel 16. Specifically, as shown in FIG. 2, it is provided between 5th connector C5 and 1st flow control device 19.

The sublimation gas supply method of this embodiment is described below.

### (2nd Heating Step)

Controller 100 exerts control to close 11th valve V11. Next, controller 100 exerts control to heat 2nd vessel 31 that houses 2nd solid material S2. Thus a 2nd sublimation gas is produced from 2nd solid material S2.

### (2nd Introduction Step)

Controller 100 exerts control to open 11th valve V11 and 12th valve V12. Then the 2nd sublimation gas is introduced into 3rd buffer tank 43.

### (2nd Switching Step)

At this time, the 1st introducing step is stopped. In other words, controller 100 exerts control to close 1st valve V1. Thereby switching from the 1st introduction step to the 2nd introduction step.

### (Vacuum Purging Step)

There may be a vacuum purging step in the 2nd switching step. The vacuum purging step comprises the following steps. Also, the following steps may be repeated.
a. Control is exerted to close 3rd valve V3, 14th valve V14 and 15th valve V15.
b. A pump (not shown in the figure) provided in discharge gas channel 23 is operated. Here, a valve (not shown in the figure) provided between the pump and discharge gas connector CE is opened. Then some of 2nd channel 16 is put in a vacuum state.
c. The valve (not shown in the figure) provided in discharge gas channel 23 is closed. Then 3rd valve V3 is opened to allow dilution gas to flow through.
d. 3rd valve V3 is closed. Then the valve (not shown in the figure) provided in discharge gas channel 23 is opened. Thus dilution gas is discharged from the discharge gas channel.

Therefore if subsequent process BP requires a solid material sublimation gas other than the 1st sublimation gas generated from 1st vessel 11, the 2nd sublimation gas from the 2nd vessel can be supplied to the subsequent process. And so with the sublimation gas supply system it is possible to supply sublimation gas continuously without stopping the system, even when the type of sublimation gas to be supplied to the subsequent process is changed. At the time of the various switching, some discharging may be performed before delivery to subsequent process BP, in order to clean the pipes and mixing vessel. And, for example, by exerting control to open 14th valve V14 and 15th valve V15 together, the 1st sublimation gas and 2nd sublimation gas may be mixed and supplied to subsequent process BP.

From that described above, many improvements and other embodiments of the present disclosure will be apparent to those skilled in the art. Therefore the descriptions above should be viewed merely as examples provided for the purpose of teaching those skilled in the art the optimum mode of executing the present disclosure. The details of the configuration and/or function can be substantially modified without departing from the essence of the present disclosure.

### INDUSTRIAL APPLICABILITY

One mode of the present disclosure can be applied in sublimation gas supply systems.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed. Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise.

“Comprising” in a claim is an open transitional term which means the subsequently identified claim elements are a nonexclusive listing i.e. anything else may be additionally included and remain within the scope of “comprising.” “Comprising” is defined herein as necessarily encompassing the more limited transitional terms “consisting essentially of” and “consisting of”: “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actor in the absence of express language in the claim to the contrary.

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

1-12. (canceled)

13. A sublimation gas supply system for supplying solid material sublimation gas to a subsequent process, the sublimation gas supply system comprising:
a 1st vessel configured to house a 1st solid material;
a 1st heater configured to heat said 1st vessel so that said 1st solid material sublimates to produce a 1st sublimation gas;
a 1st buffer tank configured to store sublimation gas;
a 1st channel configured to introduce said 1st sublimation gas into said 1st buffer tank;
a 2nd channel configured to supply said 1st sublimation gas, delivered from said 1st buffer tank, to a subsequent process;
a dilution gas channel configured to connect to a 1st connector in said 2nd channel, for introducing dilution gas into said 2nd channel;
a 1st flow control device configured to control flow, provided between said 1st connector and said 1st buffer tank on said 2nd channel;
a 2nd flow control device configured to control flow, provided on said dilution gas channel; and
a mixing vessel, provided on said 2nd channel, configured to mix said dilution gas and said 1st sublimation gas brought together by means of said 1st connector.

14. The sublimation gas supply system of claim 13, further comprising:
a 2nd buffer tank configured to store said dilution gas, provided on said dilution gas channel;
a 1st valve, provided on said 1st channel;
a 2nd valve, provided between said 1st connector and said 1st buffer tank on said 2nd channel; and
a 3rd valve, provided between said 1st connector and said 2nd buffer tank on said dilution gas channel.

15. The sublimation gas supply system of claim 14, further comprising:
a controller configured to exert control to close said 2nd valve and said 3rd valve.

16. The sublimation gas supply system of claim 13, further comprising:
a 1st discharge channel configured to discharge said 1st sublimation gas from said 1st buffer tank, provided between said 1st valve and said 1st buffer tank on said 1st channel;
a 3rd flow control device configured to control flow, provided between said mixing vessel and said subsequent process on said 2nd channel; and
a discharge gas channel configured to discharge gas on said 2nd channel, provided between said mixing vessel and said 3rd flow control device on said 2nd channel.

17. The sublimation gas supply system of claim 13, further comprising:
a 1st buffer tank heater configured to heat said 1st buffer tank; and
a mixing vessel heater configured to heat said mixing vessel.

18. The sublimation gas supply system of claim 13, further comprising:
a 2nd vessel configured to house a 2nd solid material;
a 2nd heater configured to heat said 2nd vessel so that said 2nd solid material sublimates to produce a 2nd sublimation gas; and
a 3rd channel configured to introduce said 2nd sublimation gas into said 1st buffer tank, said 1st solid material and said 2nd solid material being the same solid material.

19. The sublimation gas supply system of claim 13, further comprising:
a 2nd vessel configured to house a 2nd solid material;
a 2nd heater configured to heat said 2nd vessel so that said 2nd solid material sublimates to produce a 2nd sublimation gas;
a 3rd buffer tank configured to store said 2nd sublimation gas;
a 4th channel configured to introduce said 2nd sublimation gas into said 3rd buffer tank;
a 5th channel configured to supply said 2nd sublimation gas, delivered from said 3rd buffer tank, into said 2nd channel between said mixing vessel and said 1st buffer tank;
a 4th flow control device configured to control flow, provided on said 5th channel; and
a valve provided on said 5th channel,
whereinsaid 1st solid material and said 2nd solid material being different solid materials.

20. The sublimation gas supply system of claim 13, further comprising:
a 2nd pressure gauge configured to measure the pressure inside said 1st buffer tank; and
a controller adapted to exert control to open said 2nd valve so that said 1st sublimation gas flows through said 1st channel at start-up, when said 2nd pressure gauge reaches a predetermined pressure.

21. The sublimation gas supply system of claim 13, further comprising a controller adapted to select, during steady-state operation, or depending on the conditions of the subsequent process, at least one from the group consisting of said 1st flow control device and said 2nd flow control device to regulate the concentration of said 1st sublimation gas introduced into said subsequent process.

22. A sublimation gas supply method for supplying solid material sublimation gas to a subsequent process, the sublimation gas supply method comprising:
a 1st heating step, wherein a 1st vessel configured to house a 1st solid material is heated to produce a 1st sublimation gas from the 1st solid material;
a 1st introduction step, wherein said 1st sublimation gas is introduced into a 1st buffer tank;
a 1st supply step, wherein said 1st sublimation gas delivered from said 1st buffer tank is supplied to a subsequent process;
a 1st dilution step, wherein dilution gas is supplied to said 1st sublimation gas delivered from said 1st buffer tank;
a 1st flow control step, wherein the flow of said 1st sublimation gas delivered from said 1st buffer tank is controlled; and
a 2nd flow control step, wherein the flow of said dilution gas supplied from a dilution gas channel is controlled.

23. The sublimation gas supply method of claim 22, further comprising:
a 2nd heating step, wherein a 2nd vessel configured to house a 2nd solid material is heated to produce a 2nd sublimation gas from the 2nd solid material;
a 2nd introduction step, wherein said 2nd sublimation gas is introduced into the 1st buffer tank; and
a 1st switching step, wherein said 1st introduction step is stopped and switched to said 2nd introduction step,
wherein said 1st solid material and said 2nd solid material are the same solid material.

24. The sublimation gas supply method of claim 22, further comprising:
a 2nd heating step, wherein a 2nd vessel configured to house a 2nd solid material is heated to produce a 2nd sublimation gas from the 2nd solid material;
a 2nd introduction step, wherein said 2nd sublimation gas is introduced into a 3rd buffer tank;
a 2nd supply step, wherein said 2nd sublimation gas delivered from said 3rd buffer tank is supplied to a subsequent process;
a 2nd dilution step, wherein said dilution gas is supplied to said 2nd sublimation gas delivered from said 3rd buffer tank; and
a 2nd switching step, wherein said 1st introduction step and said 1st supply step are stopped and switched to said 2nd introduction step and said 2nd supply step, wherein said 1st solid material and said 2nd solid material are different solid materials.
